(19) United States
(12) Patent Application Publication
(10) Pub. No.: US 2022/0204009 A1
(43) Pub. Date: Jun. 30, 2022

(54) SIMULATIONS OF SENSOR BEHAVIOR IN AN AUTONOMOUS VEHICLE

(71) Applicant: WAYMO LLC, Mountain View, CA (US)

(72) Inventors: Brian Choi, Palo Alto, CA (US); Aleksandar Rumenov Gabrovski, Mountain View, CA (US); Yang-Hua Chu, Menlo Park, CA (US); Harrison McKenzie Chapter, Santa Clara, CA (US); David Richardson, Mountain View, CA (US)

(21) Appl. No.: 17/136,489

(22) Filed: Dec. 29, 2020

(51) Int. Cl. B60W 50/06; B60W 60/00

(52) U.S. Cl. CPC B60W 50/06; B60W 60/001; B60W 2554/00; B60W 2420/54; B60W 2420/52; B60W 2420/42; B60W 2420/62

(57) ABSTRACT

A simulation for sensor data may be evaluated and used for future simulations for an autonomous vehicle software. The method includes receiving log data collected for an environment along a given run for a given vehicle, using a software for autonomous driving to perform a simulated run of the given run using logged sensor data from the log data and environment data constructed using the log data, and determining first details regarding detection of objects during the given run using logged sensor data. The method also includes using the software to run a simulation of one or more detection devices on a simulated vehicle driving along the given run to obtain simulated sensor data, and determining second details regarding detection of objects using the simulated sensor data. Metrics may then be extracted from the first details and the second details, and the simulation may be evaluated based on the metrics.

### BACKGROUND

Autonomous vehicles, for instance, vehicles that do not require a human driver, can be used to aid in the transport of passengers or items from one location to another. Such vehicles may operate in a fully autonomous mode where passengers may provide some initial input, such as a pickup or destination location, and the vehicle maneuvers itself to that location, for instance, by determining and following a route which may require the vehicle to respond to and interact with other road users such as vehicles, pedestrians, bicyclists, etc. It is critical that the autonomous control software used by these vehicles to operate in the autonomous mode is tested and validated before such software is actually used to control the vehicles in areas where the vehicles are interacting with other objects.

### BRIEF SUMMARY

Aspects of the disclosure provide for a method for simulating sensor data and evaluating sensor behavior in an autonomous vehicle. The method includes receiving, by one or more processors, log data collected for an environment along a given run for a given vehicle; performing, by the one or more processors using a software for autonomous driving, a simulated run of the given run using logged sensor data from the log data and environment data constructed using the log data; determining, by the one or more processors, first details regarding detection of objects during the given run using logged sensor data; running, by the one or more processors using the software for autonomous driving, a simulation of one or more detection devices on a simulated vehicle driving along the given run to obtain simulated sensor data, the simulation including the environment data constructed using the log data; determining, by the one or more processors, second details regarding detection of objects using the simulated sensor data; extracting, by the one or more processors, one or more metrics from the first details and the second details; and evaluating, by the one or more processors, the simulation based on the one or more metrics.

In one example, the method also includes selecting, by the one or more processors, the given run based on the log data. In this example, the selecting of the given run is further based on a type of object appear along a run in the log data. In another example, the method also includes constructing, by the one or more processors, the environment data using the log data. In this example, the constructing of the environment data includes representing objects in an area encompassing the given run in a scaled mesh.

In a further example, the determining of the first details includes determining a relationship between the logged sensor data and objects represented in the environment data. In yet another example, the running of the simulation includes retracing rays transmitted from the one or more detection devices and recomputing intensities of the rays off points in the constructed environment data. In a still further example, the running of the simulation includes modeling the one or more detection devices based on configuration characteristics or operational settings of a perception system of the given vehicle. In another example, the determining of the second details includes determining a relationship between the simulated sensor data and objects represented in the environment data. In a further example, the extracting of the one or more metrics includes a first metric related to a precision of detected object types; a second metric related to an amount of recall of an object type; and a third metric related to an average detection time.

Other aspects of the disclosure provide for a non-transitory, tangible computer-readable medium on which computer-readable instructions of a program are stored. The instructions, when executed by one or more computing devices, cause the one or more computing devices to perform a method for implementing a simulation for sensor data for an autonomous vehicle. The method includes receiving log data collected for an environment along a given run for a given vehicle; performing, using a software for autonomous driving, a simulated run of the given run using logged sensor data from the log data and environment data constructed using the log data; determining first details regarding detection of objects during the given run using logged sensor data; running, using the software for autonomous driving, a simulation of one or more detection devices on a simulated vehicle driving along the given run to obtain simulated sensor data, the simulation including the environment data constructed using the log data; determining second details regarding detection of objects using the simulated sensor data; extracting one or more metrics from the first details and the second details; and evaluating the simulation based on the one or more metrics.

In one example, the method also includes selecting the given run based on the log data. In this example, the selecting of the given run is further based on a type of object appear along a run in the log data. In another example, the method also includes constructing the environment data using the log data. In this example, the constructing of the environment data includes representing objects in an area encompassing the given run in a scaled mesh.

In a further example, the determining of the first details includes determining a relationship between the logged sensor data and objects represented in the environment data. In yet another example, the running of the simulation includes retracing rays transmitted from the one or more detection devices and recomputing intensities of the rays off points in the constructed environment data. In a still further example, the running of the simulation includes modeling the one or more detection devices based on configuration characteristics or operational settings of a perception system of the given vehicle. In another example, the determining of the second details includes determining a relationship between the simulated sensor data and objects represented in the environment data. In a further example, the extracting of the one or more metrics includes a first metric related to a precision of detected object types; a second metric related to an amount of recall of an object type; and a third metric related to an average detection time.

### BRIEF DESCRIPTION OF THE DRAWINGS

FIG. 1 is a functional diagram of an example vehicle in accordance with aspects of the disclosure.

FIG. 2 is an example of map information in accordance with aspects of the disclosure.

FIG. 3 is an example external view of a vehicle in accordance with aspects of the disclosure.

FIG. 4 is a pictorial diagram of an example system in accordance with aspects of the disclosure.

FIG. 5 is a functional diagram of the system of FIG. 4 in accordance with aspects of the disclosure.

FIG. 6 is an example representation of environment data in accordance with aspects of the disclosure.

FIG. 7 is an example representation of a first simulation in accordance with aspects of the disclosure.

FIG. 8 is another example representation of a second simulation in accordance with aspects of the disclosure.

FIG. 9 is a flow diagram of an example method in accordance with in accordance with aspects of the disclosure.

FIG. 10 is a flow diagram of another example method in accordance with aspects of the disclosure.

### DETAILED DESCRIPTION

### Overview

The technology relates to using simulations to model sensor behavior in an autonomous vehicle. In particular, the sensor behavior may be evaluated to determine effectiveness of a perception system of the autonomous vehicle. A simulated run may be performed using data collected in a run of the autonomous vehicle. Metrics may be extracted from the simulated run, which can indicate how one or more sensors behaved relative to certain types of objects or relative to previous simulations.

An autonomous vehicle may be maneuvered by one or more processors using a software. The autonomous vehicle may also have a perception system configured to detect data related to objects in the vehicle's environment. A simulation system may be configured to run the software through different scenarios based at least in part on log data of the vehicle.

To model sensor behavior and evaluate for realism, the simulation system may be configured to compare sensor data from log data for a given run and simulated sensor data from a simulation of the given run. The comparison be based on resulting perception objects from perception logic that processes the sensor data and the simulated sensor data. The perception logic may be a portion of the software of the autonomous vehicle. The data and/or the resulting perception objects may be compared and evaluated using one or more metrics.

Modeling sensor behavior includes selecting a given run based on sensor data collected by a vehicle using a perception system. A time frame of about twenty seconds from the run in the log data may be selected for the given run. The one or more processors may construct environment data for a simulation using the log data. The constructed environment data may include a scaled mesh representing objects in the environment. The scaled mesh may include points from LIDAR data in the log data. The one or more processors may run the logged sensor data of the given run using the perception logic to determine details regarding detection of objects during the given run. The logged sensor data may be run in the constructed environment data to establish the relationship between the logged sensor data and objects represented in the environment. To obtain simulated sensor data, the one or more processors may run a simulation using one or more simulated detection devices of a perception system and the constructed environment data. The one or more simulated detection devices may be based on configuration characteristics or operational settings of the perception system of the vehicle during the given run. The simulation may build an environment for the given run using the constructed environment data and perform the given run using the one or more simulated detection devices on the vehicle moving through the environment. The one or more processors may then determine details regarding detection of objects in the simulated sensor data using the perception logic in a same or similar manner as described above for the logged sensor data.

The one or more processors may extract one or more metrics from the details of the logged sensor data and the details of the simulated sensor data. The one or more metrics may be measurements of how similar the simulated sensor data is to the logged sensor data. The more similar the simulated sensor data is to the logged sensor data, the more realistic the simulation is. Additionally or alternatively, the one or more metrics may compare the characteristics of a detected object in the simulation or the determined details with labels or other input by human reviewers of the logged sensor data or the constructed environment data. Based on the one or more metrics, the one or more processors may evaluate how the simulation performed. The evaluation may be for the simulated sensor or for the constructed environment. For example, the evaluation may be for realism, or how well the simulation matches what occurs on the vehicle. When the one or more metrics indicate that the simulated sensor data match or nearly matches the logged sensor data, the simulation software may be utilized in future simulations for the vehicle. The technology described herein allows for evaluation of sensor simulation that can be used to build simulation software for running future simulations. The evaluation techniques increase confidence in the sensor simulation, which results in increased confidence in simulating other aspects of autonomous vehicle navigation or developing improvements to autonomous vehicle navigation on the basis of the simulated sensors. Using the sensor simulation software validated in the manner described herein may result in a more realistic future simulation of autonomous vehicle navigation. More log data may be simulated rather than collected over many runs and many hours of driving on a roadway. More accurate tests of autonomous vehicle software may be performed in simulation, which may be more efficient and safer than running tests on a roadway. The autonomous vehicle software may be continually improved using the simulation technology.

### Example Systems

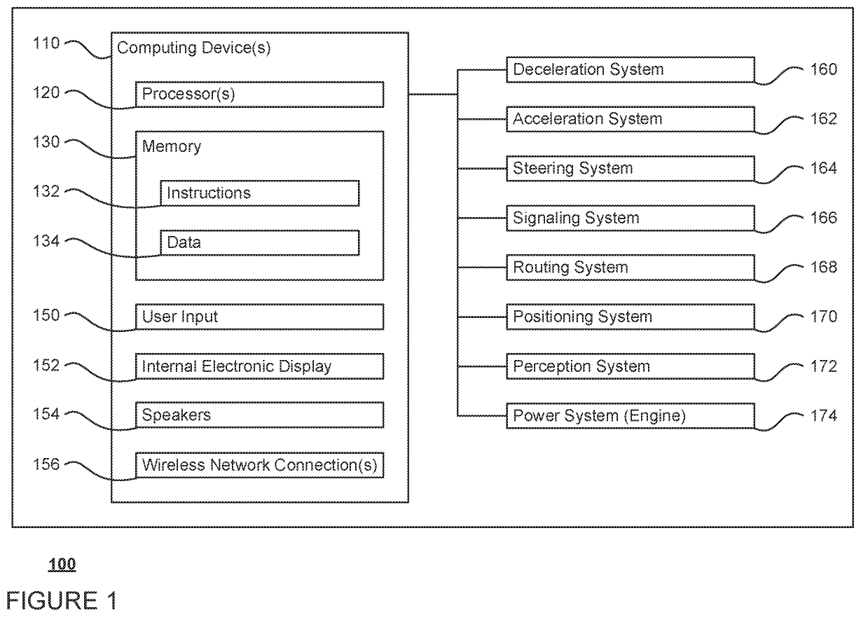

As shown in FIG. 1, a vehicle 100 in accordance with one aspect of the disclosure includes various components. While certain aspects of the disclosure are particularly useful in connection with specific types of vehicles, the vehicle may be any type of vehicle including, but not limited to, cars, trucks, motorcycles, buses, recreational vehicles, etc. The vehicle may have one or more computing devices, such as computing devices 110 containing one or more processors 120, memory 130 and other components typically present in general purpose computing devices.

The memory 130 stores information accessible by the one or more processors 120, including instructions 134 and data 132 that may be executed or otherwise used by the processor 120. The memory 130 may be of any type capable of storing information accessible by the processor, including a computing device-readable medium, or other medium that stores data that may be read with the aid of an electronic device, such as a hard-drive, memory card, ROM, RAM, DVD or other optical disks, as well as other write-capable and read-only memories. Systems and methods may include different combinations of the foregoing, whereby different portions of the instructions and data are stored on different types of media.

The instructions 134 may be any set of instructions to be executed directly (such as machine code) or indirectly (such as scripts) by the processor. For example, the instructions may be stored as computing device code on the computing device-readable medium. In that regard, the terms “software,” “instructions” and “programs” may be used interchangeably herein. The instructions may be stored in object code format for direct processing by the processor, or in any other computing device language including scripts or collections of independent source code modules that are interpreted on demand or compiled in advance. Functions, methods and routines of the instructions are explained in more detail below.

The data 132 may be retrieved, stored or modified by processor 120 in accordance with the instructions 134. For instance, although the claimed subject matter is not limited by any particular data structure, the data may be stored in computing device registers, in a relational database as a table having a plurality of different fields and records, XML documents or flat files. The data may also be formatted in any computing device-readable format.

The one or more processors 120 may be any conventional processors, such as commercially available CPUs. Alternatively, the one or more processors may be a dedicated device such as an ASIC or other hardware-based processor. Although FIG. 1 functionally illustrates the processor, memory, and other elements of computing devices 110 as being within the same block, it will be understood by those of ordinary skill in the art that the processor, computing device, or memory may actually include multiple processors, computing devices, or memories that may or may not be stored within the same physical housing. For example, memory may be a hard drive or other storage media located in a housing different from that of computing devices 110. Accordingly, references to a processor or computing device will be understood to include references to a collection of processors or computing devices or memories that may or may not operate in parallel.

Computing devices 110 may have all of the components normally used in connection with a computing device such as the processor and memory described above as well as a user input 150 (e.g., a mouse, keyboard, touch screen and/or microphone) and various electronic displays (e.g., a monitor having a screen or any other electrical device that is operable to display information). In this example, the vehicle includes an internal electronic display 152 as well as one or more speakers 154 to provide information or audio-visual experiences. In this regard, internal electronic display 152 may be located within a cabin of vehicle 100 and may be used by computing devices 110 to provide information to passengers within the vehicle 100.

Computing devices 110 may also include one or more wireless network connections 156 to facilitate communication with other computing devices, such as the client computing devices and server computing devices described in detail below. The wireless network connections may include short range communication protocols such as Bluetooth, Bluetooth low energy (LE), cellular connections, as well as various configurations and protocols including the Internet, World Wide Web, intranets, virtual private networks, wide area networks, local networks, private networks using communication protocols proprietary to one or more companies, Ethernet, WiFi and HTTP, and various combinations of the foregoing.

In one example, computing devices 110 may be control computing devices of an autonomous driving computing system or incorporated into vehicle 100. The autonomous driving computing system may capable of communicating with various components of the vehicle in order to control the movement of vehicle 100 according to the autonomous control software of memory 130 as discussed further below. For example, returning to FIG. 1, computing devices 110 may be in communication with various systems of vehicle 100, such as deceleration system 160, acceleration system 162, steering system 164, signaling system 166, routing system 168, positioning system 170, perception system 172, and power system 174 (i.e., the vehicle's engine or motor) in order to control the movement, speed, etc. of vehicle 100 in accordance with the instructions 134 of memory 130. Again, although these systems are shown as external to computing devices 110, in actuality, these systems may also be incorporated into computing devices 110, again as an autonomous driving computing system for controlling vehicle 100. The autonomous control software may include sections, or logic, directed to controlling or communicating with specific systems of the vehicle 100.

As an example, computing devices 110 may interact with one or more actuators of the deceleration system 160 and/or acceleration system 162, such as brakes, accelerator pedal, and/or the engine or motor of the vehicle, in order to control the speed of the vehicle. Similarly, one or more actuators of the steering system 164, such as a steering wheel, steering shaft, and/or pinion and rack in a rack and pinion system, may be used by computing devices 110 in order to control the direction of vehicle 100. For example, if vehicle 100 is configured for use on a road, such as a car or truck, the steering system may include one or more actuators to control the angle of wheels to turn the vehicle. Signaling system 166 may be used by computing devices 110 in order to signal the vehicle's intent to other drivers or vehicles, for example, by lighting turn signals or brake lights when needed.

Routing system 168 may be used by computing devices 110 in order to determine and follow a route to a location. In this regard, the routing system 168 and/or data 132 may store detailed map information, e.g., highly detailed maps identifying the shape and elevation of roadways, lane lines, intersections, crosswalks, speed limits, traffic signals, buildings, signs, real time traffic information, vegetation, or other such objects and information.

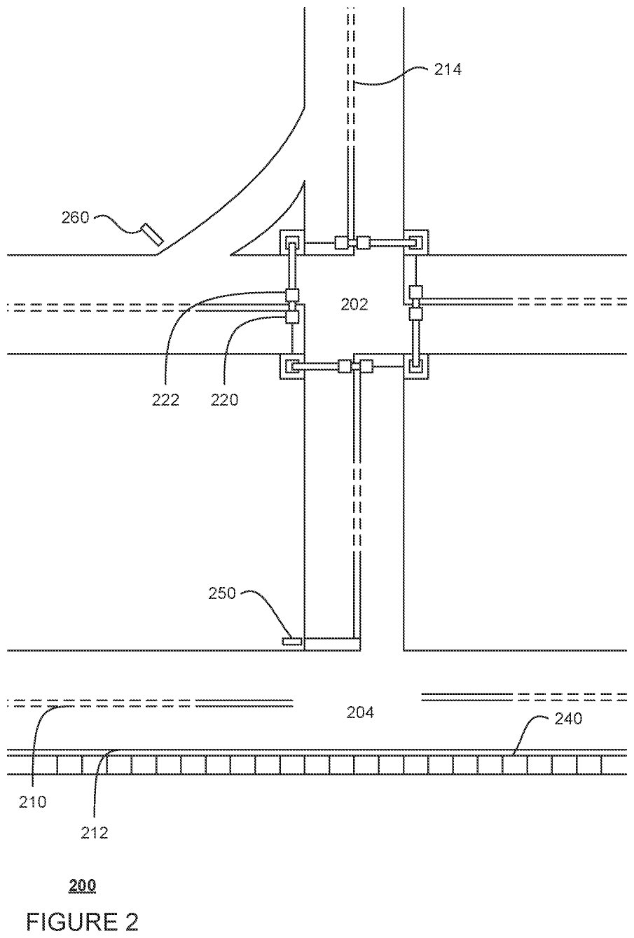

FIG. 2 is an example of map information 200 for a section of roadway including intersections 202 and 204. In this example, the map information 200 includes information identifying the shape, location, and other characteristics of lane lines 210, 212, 214, traffic signal lights 220, 222, sidewalk 240, stop sign 250, and yield sign 260. Although the map information is depicted herein as an image-based map, the map information need not be entirely image based (for example, raster). For example, the map information may include one or more roadgraphs or graph networks of information such as roads, lanes, intersections, and the connections between these features. Each feature may be stored as graph data and may be associated with information such as a geographic location and whether or not it is linked to other related features, for example, a stop sign may be linked to a road and an intersection, etc. In some examples, the associated data may include grid-based indices of a roadgraph to allow for efficient lookup of certain roadgraph features.

Positioning system 170 may be used by computing devices 110 in order to determine the vehicle's relative or absolute position on a map or on the earth. For example, the position system 170 may include a GPS receiver to determine the device's latitude, longitude and/or altitude position. Other location systems such as laser-based localization systems, inertial-aided GPS, or camera-based localization may also be used to identify the location of the vehicle. The location of the vehicle may include an absolute geographical location, such as latitude, longitude, and altitude as well as relative location information, such as location relative to other cars immediately around it which can often be determined with less noise that absolute geographical location.

The positioning system 170 may also include other devices in communication with computing devices 110, such as an accelerometer, gyroscope or another direction/speed detection device to determine the direction and speed of the vehicle or changes thereto. By way of example only, an acceleration device may determine its pitch, yaw or roll (or changes thereto) relative to the direction of gravity or a plane perpendicular thereto. The device may also track increases or decreases in speed and the direction of such changes. The device's provision of location and orientation data as set forth herein may be provided automatically to the computing devices 110, other computing devices and combinations of the foregoing.

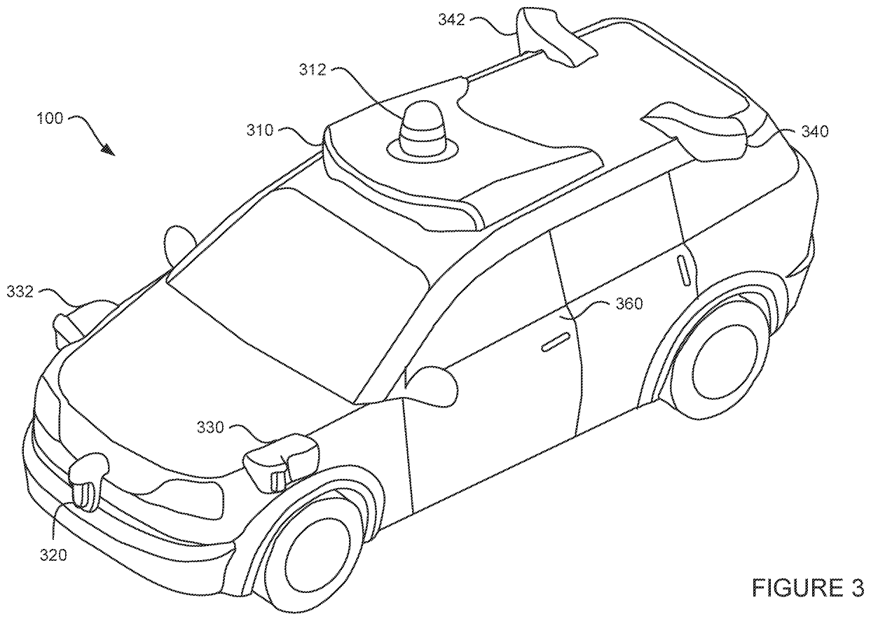

The perception system 172 also includes one or more components for detecting objects external to the vehicle such as other vehicles, obstacles in the roadway, traffic signals, signs, trees, etc. For example, the perception system 172 may include lasers, sonar, radar, cameras and/or any other detection devices that record data which may be processed by computing device 110. In the case where the vehicle is a passenger vehicle such as a minivan, the minivan may include a laser or other sensors mounted on the roof or other convenient location. For instance, FIG. 3 is an example external view of vehicle 100. In this example, roof-top housing 310 and dome housing 312 may include a LIDAR sensor as well as various cameras and radar units. In addition, housing 320 located at the front end of vehicle 100 and housings 330, 332 on the driver's and passenger's sides of the vehicle may each store a LIDAR sensor. For example, housing 330 is located in front of driver door 360. Vehicle 100 also includes housings 340, 342 for radar units and/or cameras also located on the roof of vehicle 100. Additional radar units and cameras (not shown) may be located at the front and rear ends of vehicle 100 and/or on other positions along the roof or roof-top housing 310.

The computing devices 110 may control the direction and speed of the vehicle by controlling various components. By way of example, computing devices 110 may navigate the vehicle to a destination location completely autonomously using data from the detailed map information and routing system 168. Computing devices 110 may use the positioning system 170 to determine the vehicle's location and perception system 172 to detect and respond to objects when needed to reach the location safely. In order to do so, computing devices 110 may cause the vehicle to accelerate (e.g., by increasing fuel or other energy provided to the engine by acceleration system 162), decelerate (e.g., by decreasing the fuel supplied to the engine, changing gears, and/or by applying brakes by deceleration system 160), change direction (e.g., by turning the front or rear wheels of vehicle 100 by steering system 164), and signal such changes (e.g., by lighting turn signals of signaling system 166). Thus, the acceleration system 162 and deceleration system 160 may be a part of a drivetrain that includes various components between an engine of the vehicle and the wheels of the vehicle. Again, by controlling these systems, computing devices 110 may also control the drivetrain of the vehicle in order to maneuver the vehicle autonomously.

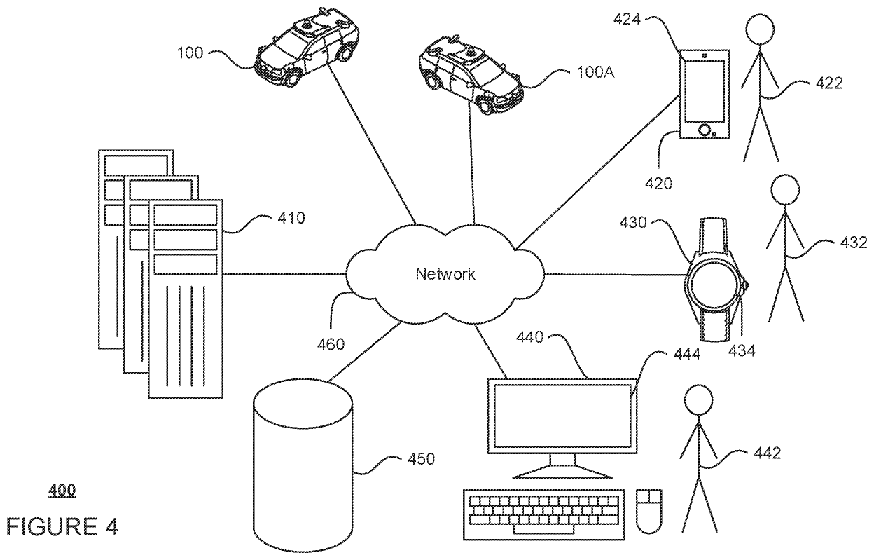

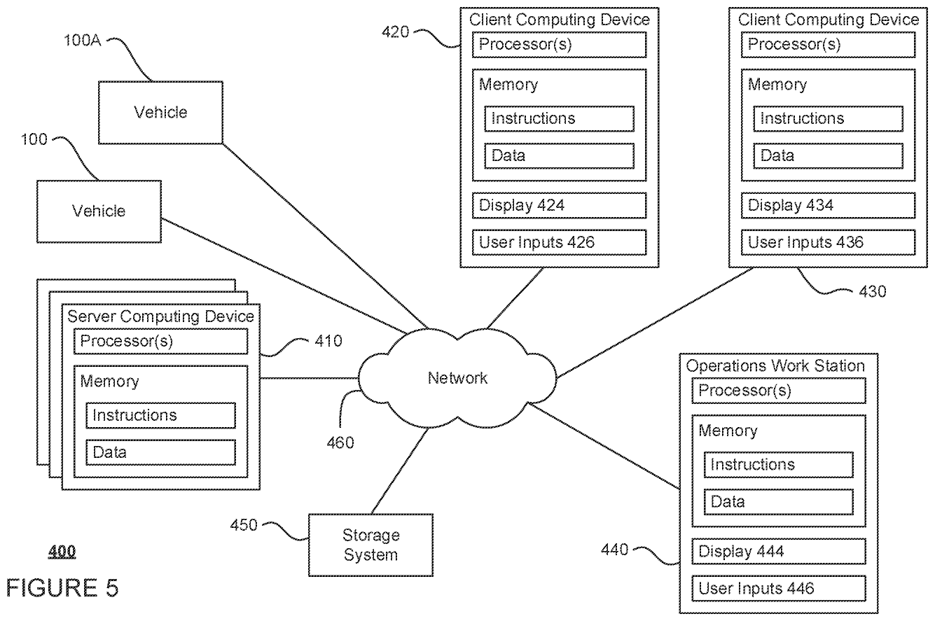

Computing device 110 of vehicle 100 may also receive or transfer information to and from other computing devices, such as those computing devices that are a part of the transportation service as well as other computing devices. FIGS. 4 and 5 are pictorial and functional diagrams, respectively, of an example system 400 that includes a plurality of computing devices 410, 420, 430, 440 and a storage system 450 connected via a network 460. System 400 also includes vehicle 100 and vehicle 100A, which may be configured the same as or similarly to vehicle 100. Although only a few vehicles and computing devices are depicted for simplicity, a typical system may include significantly more.

As shown in FIG. 4, each of computing devices 410, 420, 430, 440 may include one or more processors, memory, data and instructions. Such processors, memories, data and instructions may be configured similarly to one or more processors 120, memory 130, data 132, and instructions 134 of computing device 110.

The network 460, and intervening nodes, may include various configurations and protocols including short range communication protocols such as Bluetooth, Bluetooth LE, the Internet, World Wide Web, intranets, virtual private networks, wide area networks, local networks, private networks using communication protocols proprietary to one or more companies, Ethernet, WiFi and HTTP, and various combinations of the foregoing. Such communication may be facilitated by any device capable of transmitting data to and from other computing devices, such as modems and wireless interfaces.

In one example, one or more computing devices 410 may include one or more server computing devices having a plurality of computing devices, e.g., a load balanced server farm, that exchange information with different nodes of a network for the purpose of receiving, processing and transmitting the data to and from other computing devices. For instance, one or more computing devices 410 may include one or more server computing devices that are capable of communicating with computing device 110 of vehicle 100 or a similar computing device of vehicle 100A as well as computing devices 420, 430, 440 via the network 460. For example, vehicles 100, 100A, may be a part of a fleet of vehicles that can be dispatched by server computing devices to various locations. In this regard, the server computing devices 410 may function as a simulation system which can be used to validate autonomous control software which vehicles such as vehicle 100 and vehicle 100A may use to operate in an autonomous driving mode. The simulation system may additionally or alternatively be used to run simulations for the autonomous control software as further described below. In addition, server computing devices 410 may use network 460 to transmit and present information to a user, such as user 422, 432, 442 on a display, such as displays 424, 434, 444 of computing devices 420, 430, 440. In this regard, computing devices 420, 430, 440 may be considered client computing devices.

As shown in FIG. 4, each client computing device 420, 430, 440 may be a personal computing device intended for use by a user 422, 432, 442, and have all of the components normally used in connection with a personal computing device including a one or more processors (e.g., a central processing unit (CPU)), memory (e.g., RAM and internal hard drives) storing data and instructions, a display such as displays 424, 434, 444 (e.g., a monitor having a screen, a touch-screen, a projector, a television, or other device that is operable to display information), and user input devices 426, 436, 446 (e.g., a mouse, keyboard, touchscreen or microphone). The client computing devices may also include a camera for recording video streams, speakers, a network interface device, and all of the components used for connecting these elements to one another.

Although the client computing devices 420, 430, and 440 may each comprise a full-sized personal computing device, they may alternatively comprise mobile computing devices capable of wirelessly exchanging data with a server over a network such as the Internet. By way of example only, client computing device 420 may be a mobile phone or a device such as a wireless-enabled PDA, a tablet PC, a wearable computing device or system, or a netbook that is capable of obtaining information via the Internet or other networks. In another example, client computing device 430 may be a wearable computing system, shown as a wristwatch as shown in FIG. 4. As an example the user may input information using a small keyboard, a keypad, microphone, using visual signals with a camera, or a touch screen.

In some examples, client computing device 440 may be an operations workstation used by an administrator or operator to review simulation outcomes, handover times, and validation information. Although only a single operations workstation 440 is shown in FIGS. 4 and 5, any number of such work stations may be included in a typical system. Moreover, although the operations workstation is depicted as a desktop computer, operations workstations may include various types of personal computing devices such as laptops, netbooks, tablet computers, etc.

As with memory 130, storage system 450 can be of any type of computerized storage capable of storing information accessible by the server computing devices 410, such as a hard-drive, memory card, ROM, RAM, DVD, CD-ROM, write-capable, and read-only memories. In addition, storage system 450 may include a distributed storage system where data is stored on a plurality of different storage devices which may be physically located at the same or different geographic locations. Storage system 450 may be connected to the computing devices via the network 460 as shown in FIGS. 4 and 5, and/or may be directly connected to or incorporated into any of the computing devices 110, 410, 420, 430, 440, etc.

Storage system 450 may store various types of information as described in more detail below. This information may be retrieved or otherwise accessed by a server computing device, such as one or more server computing devices 410, in order to perform some or all of the features described herein. For instance, storage system 450 may store log data. This log data may include, for instance, sensor data generated by a perception system, such as perception system 172 of vehicle 100 as the vehicle is being driven autonomously or manually. Additionally or alternatively, the log data may be generated from one or more sensors positioned along a roadway or mounted on another type of vehicle, such as an aerial vehicle. As an example, the sensor data may include raw sensor data as well as data identifying defining characteristics of perceived objects such as shape, location, orientation, speed, etc. of objects such as vehicles, pedestrians, bicyclists, vegetation, curbs, lane lines, sidewalks, crosswalks, buildings, etc. The log data may also include “event” data identifying different types of events such as collisions or near collisions with other objects, planned trajectories describing a planned geometry and/or speed for a potential path of the vehicle 100, actual locations of the vehicle at different times, actual orientations/headings of the vehicle at different times, actual speeds, accelerations and decelerations of the vehicle at different times, classifications of and responses to perceived objects, behavior predictions of perceived objects, status of various systems (such as acceleration, deceleration, perception, steering, signaling, routing, power, etc.) of the vehicle at different times including logged errors, inputs to and outputs of the various systems of the vehicle at different times, etc. As such, these events and the sensor data may be used to “recreate” the vehicle's environment, including perceived objects, and behavior of a vehicle in a simulation.

In addition, the storage system 450 may also store autonomous control software which is to be used by vehicles, such as vehicle 100, to operate a vehicle in an autonomous driving mode. This autonomous control software stored in the storage system 450 may be a version which has not yet been validated. Once validated, the autonomous control software may be sent, for instance, to memory 130 of vehicle 100 in order to be used by computing devices 110 to control vehicle 100 in an autonomous driving mode.

### Example Methods

In addition to the operations described above and illustrated in the figures, various operations will now be described. It should be understood that the following operations do not have to be performed in the precise order described below. Rather, various steps can be handled in a different order or simultaneously, and steps may also be added or omitted.

To model and evaluate behavior of the perception system 172, the server computing devices 410 may run simulations of various scenarios for an autonomous vehicle. In particular, a simulation may be run to compare sensor data from log data for a given run and simulated sensor data from a simulation of the given run. In some implementations, the simulation may be for a particular sensor or detection device or group of sensors or detection devices, such as LIDAR, radar, or cameras. The sensor data from the log data may be from the aforementioned log data of storage system 450. The comparison may be based on resulting perception objects from perception logic that processes the sensor data and the simulated sensor data. The data and/or the resulting perception objects may be compared and evaluated using one or more metrics.

Modeling sensor behavior includes the server computing devices 410 selecting a given run based on log data collected by a vehicle using a perception system, such as vehicle 100 using perception system 172. The vehicle may or may not be capable of driving autonomously. The given run may be selected from the log data based on certain criteria or based on user selections. The certain criteria may include one or more types of objects detectable by the perception logic, such as pedestrians, cyclist, vehicles, motorcycles, foliage, sidewalks, adults, children, or free space. For example, the server computing devices 410 or the user selections may identify a point at which the one or more type of objects appear along a run in the log data. A time frame of about twenty seconds from the run in the log data may be selected for the given run, such as a time frame including ten seconds before where the vehicle detects an object of the one or more type of objects and ten seconds after where the vehicle detects the object. Different time frames may be used in other runs or implementations.

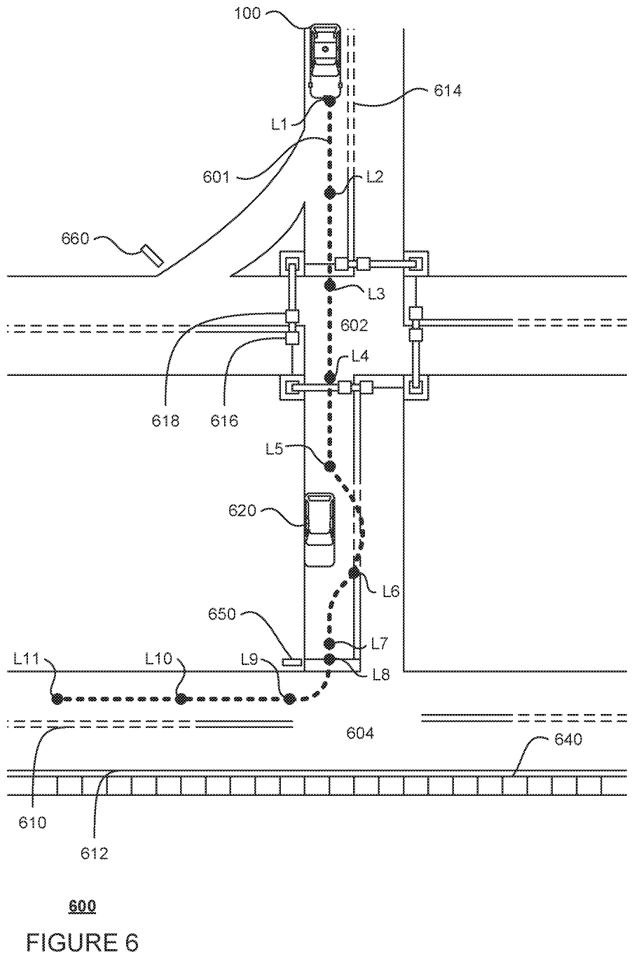

As shown in FIG. 6, a given run 601 in the area 600 corresponding to map information 200 may be selected based on criteria including a vehicle parked along a curb. An agent vehicle 620 is in a same lane as a simulated autonomous vehicle corresponding vehicle 100 and is parked along the curb in between the initial location of the simulated autonomous vehicle and the intersection 604. In this example, intersections 602 and 604 correspond to intersections 202 and 204, respectively. This regard, the shape, location, and other characteristics of lane lines 610, 612, 614, traffic signal lights 616, 618, sidewalk 640, stop sign 650, and yield sign 660 corresponds to the shape, location and other characteristics of lane lines 210, 212, 214, traffic signal lights 220, 222, sidewalk 240, stop sign 250, and yield sign 260.

The given run 601 may comprise the locations logged by the vehicle 100 during ten seconds of driving in the area 600. In the given run 601, the vehicle is approaching an intersection 604 from an initial location in a first direction. In FIG. 6, the given run 601 is broken down into a plurality of vehicle locations at particular timestamps. The timestamps may correspond to the refresh rate for the sensors or detection devices in the perception system 172, such as every 1/10 second, or more or less. For the sake of simplicity, the given run 601 is shown broken down into eleven vehicle locations L1-L11 at eleven timestamps T1-T11, one second apart from each other. In some implementations, the timestamps may differ for different sensors or detection devices.

The server computing devices 410 may construct environment data for a simulation using the log data. For example, the server computing devices 410 may use log data to identify static scenery and perception objects in the area encompassing the given run. The log data used to construct environment data may include data collected before or after the given run. For constructing the static scenery or non-static scenery, the data used may include data collected on a different day, data collected by different vehicles or devices, or map data. The constructed environment data may include a scaled mesh representing objects in the environment. The scaled mesh may include points from LIDAR data in the log data. In some implementations, the constructed environment data may include regenerated mesh points based on the LIDAR data in the log data.

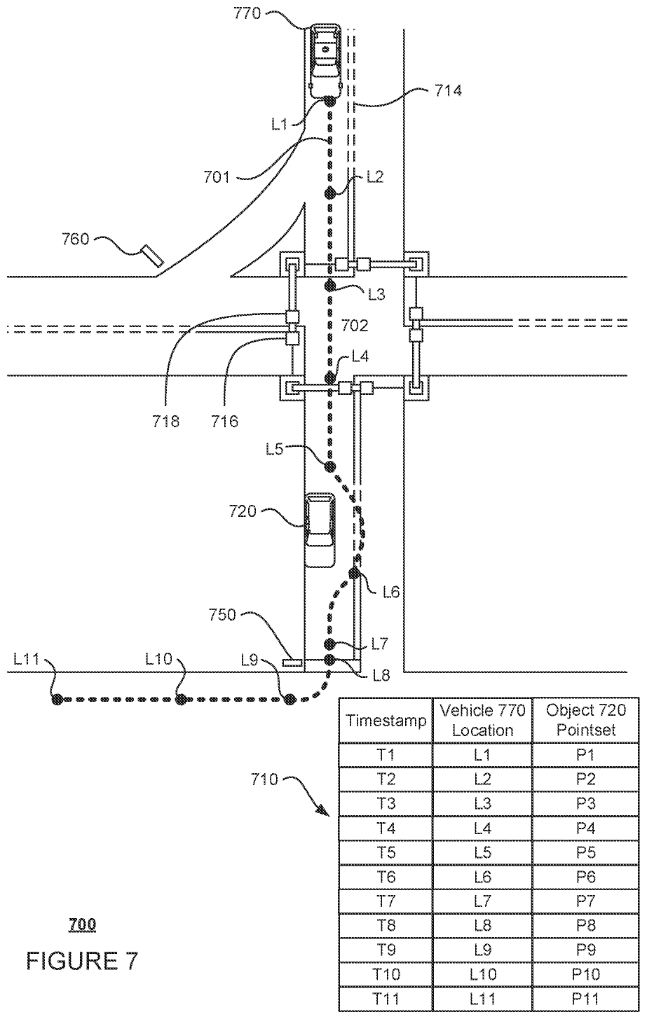

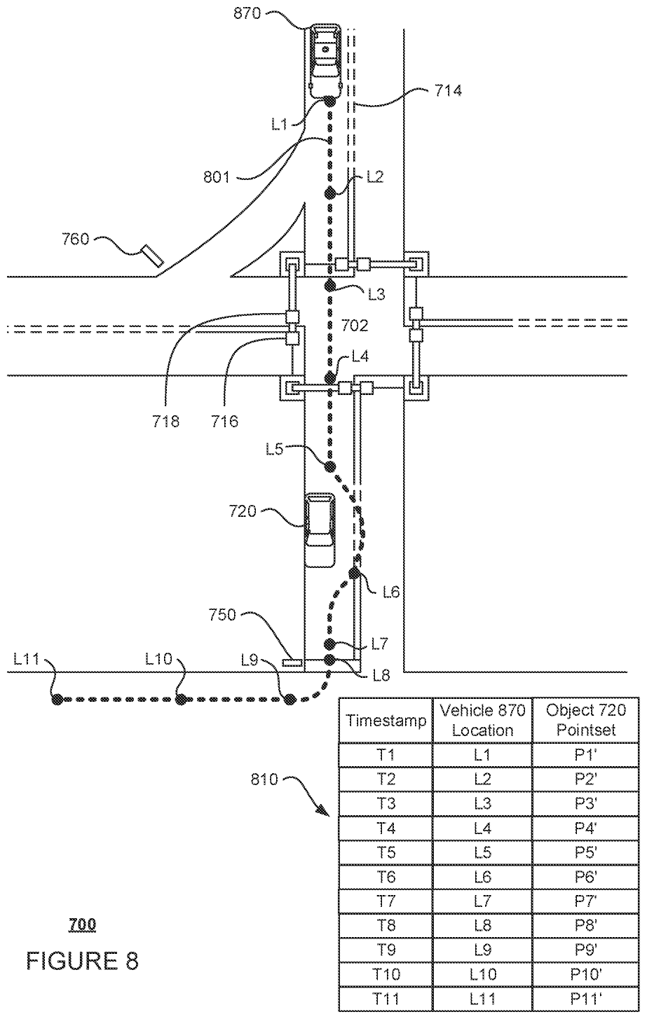

In the example shown in FIG. 6, the log data for the given run 601 includes static objects in the environment of the vehicle 100, such as traffic signal lights 616, 618, stop sign 650, yield sign 660, and agent vehicle 620. For the traffic signal lights 616, 618, the stop sign 650, and/or the yield sign 650, the server computing devices 410 may use known dimensions, map information 200, and/or sensor data collected from different angles with respect to these static objects to construct the scaled mesh representing the entirety of each of these objects in the simulated environment. For the agent vehicle 620, the server computing devices 410 may use known dimensions of the make and model of the agent vehicle 620 to construct the scaled mesh representing the entirety of the agent vehicle 620 in the simulated environment. The resulting environment data 700 is used in the simulated run and other simulations as discussed further below with respect to FIGS. 7 and 8.

The server computing devices 410 may perform a simulated run of the given run to compare the logged sensor data with objects represented in the environment data. The perception logic may be used by the server computing devices 410 to determine first details regarding detection of objects during the given run, such as how data is received from objects in the environment data using one or more detection devices in the perception system 172 and how the data is then processed. In addition, the logged sensor data may be run in the constructed environment data to establish the relationship between the logged sensor data and objects represented in the environment. The logged sensor data may include camera image data. In some implementations, the sensor data and the perception logic used at this step may be for a particular sensor or detection device or a group of sensors or detection devices in the perception system 172 that is selected for testing. The particular sensor or detection device may be selected based on user input received by the server computing devices 410. In addition, a particular configuration for the particular sensor or detection device may be used for the simulated run, including such as location, pointing direction, or field of view. The perception logic used at this step may be used in a particular manner to alter or mutate simulated sensor data in a desired way. The first details determined regarding the detection of objects may include shape of a detected object, a location of the detected object, and/or a point in time when the object is detected. For example, the first details may include or be extracted based on a collection of points, or pointset, from the constructed scaled mesh that are associated with a particular object.

FIG. 7 shows a simulated run 701 of the log data in the constructed environment data 700. The constructed environment data 700 includes intersection 702 and lane lines 714, as well as reconstructions of objects that were detected in the log data shown in FIG. 6. For example, traffic signal lights 616, 618, stop sign 650, yield sign 660, agent vehicle 620, and other features in the area 600 may be reconstructed as traffic signal lights 716, 718, stop sign 750, yield sign 760, agent vehicle 720 and other features in simulated environment. The server computing devices 410 may determine the relationship between the logged sensor data and objects represented in the environment by determining the pointset in the environment that correspond to the logged sensor data and comparing the pointset to the logged sensor data. As shown in table 710 in FIG. 7, the object pointsets P1-P11 may be determined for each timestamp T1-T11 corresponding to log data collected from respective vehicle locations L1-L11 by a simulated vehicle 770 that corresponds to vehicle 100. The table 710 may additionally or alternatively include other details of the simulated run 701, such as vehicle speed, vehicle pose, detection device settings or configurations, intensity of reflected signals, or other types of data points reflecting the detected objects. The details of the object pointset, such as for agent vehicle 720, may be detected or derived using the collection of points in the pointset, including shape of the detected portion of the object and location of the detected portion of the object.

To obtain simulated sensor data, the server computing devices 410 may run a simulation using one or more simulated detection devices of the perception system 172 and the constructed environment data. The simulation may include retracing rays transmitted from the one or more simulated detection devices and recompute intensities of the reflected rays off points in the constructed environment data. The one or more simulated detection devices may be based on configuration characteristics or operational settings of the perception system 172 of the vehicle 100 during the given run. For example, the configuration characteristics may include types of transmitters or receivers, types of lenses, connections between components, or position relative to the vehicle 100, and the operational settings may include frequency of data capture, signal frequencies, or pointing directions. The simulation may build an environment for the given run using the constructed environment data and perform the given run using the one or more simulated detection devices on the vehicle moving through the environment. The given run may be performed in the simulation at a same day and time, along a same path, and in a same manner as the given run in the log data. The same path may be a path corresponding to the time frame for the given run.

The server computing devices 410 may then determine second details regarding detection of objects in the simulated sensor data using the perception logic in a same or similar manner as described above for the first details of the logged sensor data. For example, the second details may include how data is received from objects in the environment data by the one or more simulated detection devices in the perception system 172 and how the data is then processed. In addition, the relationship between the simulated sensor data and objects represented in the environment may be determined for the second details. In some implementations, the sensor data and the perception logic used at this step may be for a particular sensor or detection device in the perception system 172 that is selected for testing. The particular sensor or detection device may be selected based on user input received by the server computing devices 410. The second details determined regarding the detection of objects may include shape of a detected object, a location of the detected object, and/or a point in time when the object is detected. For example, the second details may include or be extracted based on a collection of points, or pointset, from the constructed scaled mesh that are associated with a particular object.

As shown in FIG. 8, a simulation of a run 801 may be run in the constructed environment data 700. The run 801 for simulated vehicle 870 may match the vehicle locations over time of the given run 601 from the log data and/or the simulated run 701 for the log data. As shown in table 810, the timestamps T1-T11 and vehicle locations L1-L11 match that of table 710 in FIG. 7. The object pointsets for agent vehicle 720 based on the one or more simulated detection devices are P1′-P11′ for each respective timestamp T1-T11. The object pointsets P1′-P11′ may differ from the object pointsets P1-P11 due to differences between the simulated detection devices and the detection devices that collected the logged sensor data, differences between the perception logic in the simulated run 801 and that of the simulated run 701, and/or differences between the constructed environment 700 and the actual environment.

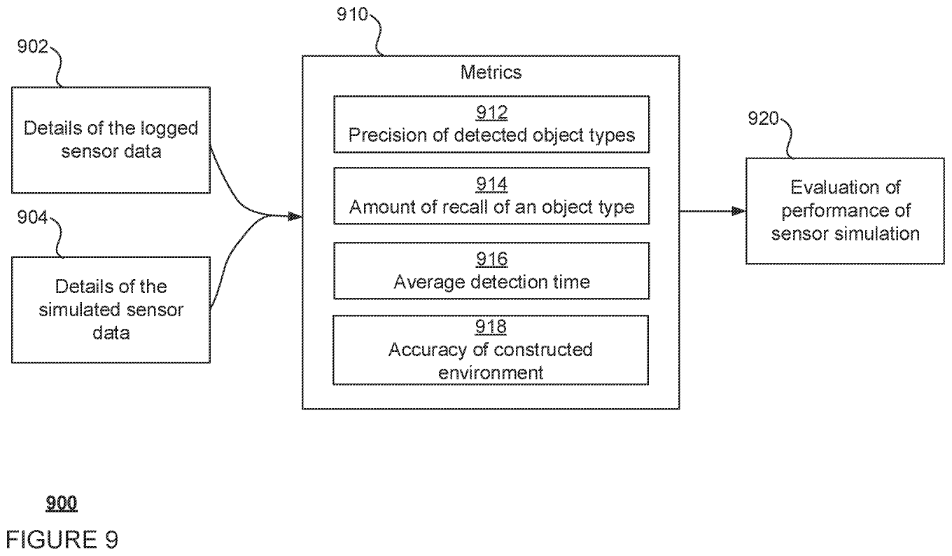

The server computing devices 410 may extract one or more metrics from the first details of the logged sensor data and the second details of the simulated sensor data. The one or more metrics may be measurements of how similar the simulated sensor data is to the logged sensor data. The more similar the simulated sensor data is to the logged sensor data, the more realistic the simulation is. As shown in flow diagram 900 shown in FIG. 9, the first details of the logged sensor data 902 and the second details of the simulated sensor data 904 may both be used to determine one or more metrics 910. The logged sensor data 902 may include the object 720 pointsets P1-P11 or other data related to the logged sensor data in the simulated run 701, and the simulated sensor data 904 may include object 720 pointsets P1′-P11′ or other data related to the simulated sensor data. The one or more metrics 910 may include a first metric 912 related to the precision of detected object types, a second metric 914 related to the amount of recall of an object type, or a third metric 916 related to the average detection time. The precision of detected object types may be based on a location of a type of object were detected in the simulation in comparison to a location of the type of object detected in the determined details. The recall of an object type may be based on a number of a type of object were detected in the simulation in comparison to a number of the type of object detected in the determined details. The average detection time may be based on a time when an object is detected in the simulation in comparison to a time when the object is detected in the determined details. Additionally or alternatively, the one or more metrics may include a fourth metric 918 related to how accurately the constructed environment data reflects the actual environment, such as one or more errors in the simulated data or one or more discrepancies between the logged sensor data and the constructed environment data. For example, an environmental metric may be a number of instances when static scenery is detected as part of a dynamic object.

Additionally or alternatively, the one or more metrics may compare the characteristics of a detected object in the simulation or the determined details with labels or other input by human reviewers of the logged sensor data or the constructed environment data. These one or more metrics may be measurements of how similar the simulated or logged sensor data are to what a human driver sees. The more similar the simulated or logged sensor data is to the human reviewer input, the more accurately the data reflects the ground truths in the environment.

Based on the one or more metrics 910, the server computing devices 410 or other one or more processors may perform an evaluation 920 of how the simulation performed. The evaluation may be for the simulated sensor or for the constructed environment. For example, the evaluation may be for realism, or how well the simulation matches what occurred in the perception system 172 of the vehicle 100. Additionally or alternatively, the evaluation may be for how well the constructed environment matches the ground truths in the environment. The one or more metrics may be tracked over multiple simulations of a same scenario or different scenarios to determine whether the simulated sensor data matches or nearly matches the logged sensor data.

When the one or more metrics indicate that the simulated sensor data match or nearly matches the logged sensor data, the simulation software may be utilized in future simulations for the vehicle. A future simulation may be used to identify bugs in the autonomous vehicle software or find areas of improvement for the autonomous vehicle software. In some implementations, a future simulation may test how the objects detected by a sensor configuration or a perception logic compares to objects in the environment data. In other implementations, the future simulation may test how changes in the sensor configuration (different settings, different setup, new sensors, etc.) or changes in the perception logic alters object detection effectiveness in comparison to a current configuration or perception logic. The one or more metrics may be determined for the future simulations to evaluate whether the object detection effectiveness is improved from the current configuration or perception logic. In further implementations, the simulation software may be used to simulate a partial amount of sensor data in a future simulation, such as sensor data for some of the detection devices on the vehicle and not others, or some types of sensor data (such as sensor field of view or contours) and not others.

In some alternative implementations, the simulation may be configured to simulate at least a portion of a path different from the path of the vehicle in the log data. For example, the one or more processors may determine a different path in the time frame through the constructed environment data, as well as a simulated pose of each simulated detection device along the different path to obtain the simulated sensor data.

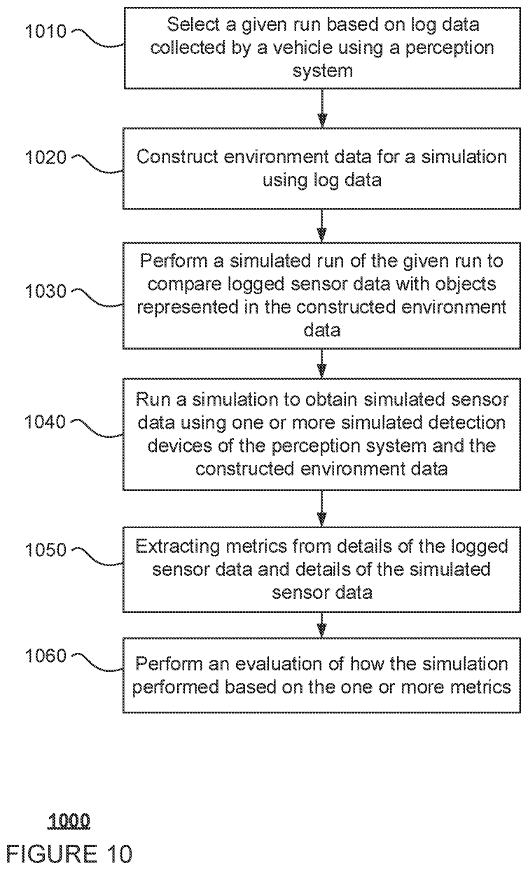

FIG. 10 shows an example flow diagram 1000 of some of the methods for evaluating a simulation system configured to simulate behavior of one or more sensors in an autonomous vehicle, which may be performed by one or more processors such as processors of computing devices 410. For instance, at block 1010, a given run may be selected based on log data collected by a vehicle using a perception system. At block 1020, environment data may be constructed for a simulation using the log data. At block 1030, a simulated run of the given run may be performed to compare logged sensor data with objects represented in the constructed environment data. From the simulated run and the logged sensor data, first details regarding detection of objects during the given run may be determined. At block 1040, a simulation may be run to obtain simulated sensor data using one or more simulated detection devices of the perception system and the constructed environment data. From the simulated sensor data, second details regarding detection of objects using the one or more simulated detection devices may be determined. At block 1050, one or more metrics may be extracted from first details of the logged sensor data and second details of the simulated sensor data. At block 1060, an evaluation of how the simulation performed may be performed based on the one or more metrics.

The technology described herein allows for evaluation of sensor simulation that can be used to build simulation software for running future simulations. The evaluation techniques increase confidence in the sensor simulation, which results in increased confidence in simulating other aspects of autonomous vehicle navigation or developing improvements to autonomous vehicle navigation on the basis of the simulated sensors. Using the sensor simulation software validated in the manner described herein may result in a more realistic future simulation of autonomous vehicle navigation. More log data may be simulated rather than collected over many runs and many hours of driving on a roadway. More accurate tests of autonomous vehicle software may be performed in simulation, which may be more efficient and safer than running tests on a roadway. The autonomous vehicle software may be continually improved using the simulation technology.

Unless otherwise stated, the foregoing alternative examples are not mutually exclusive, but may be implemented in various combinations to achieve unique advantages. As these and other variations and combinations of the features discussed above can be utilized without departing from the subject matter defined by the claims, the foregoing description of the embodiments should be taken by way of illustration rather than by way of limitation of the subject matter defined by the claims. In addition, the provision of the examples described herein, as well as clauses phrased as “such as,” “including” and the like, should not be interpreted as limiting the subject matter of the claims to the specific examples; rather, the examples are intended to illustrate only one of many possible embodiments. Further, the same reference numbers in different drawings can identify the same or similar elements.

1. A method for simulating sensor data for an autonomous vehicle, the method comprising:
receiving, by one or more processors, log data collected for an environment along a given run for a given vehicle;
performing, by the one or more processors using a software for autonomous driving, a simulated run of the given run using logged sensor data from the log data and environment data constructed using the log data;
determining, by the one or more processors, first details regarding detection of objects during the given run using logged sensor data;
running, by the one or more processors using the software for autonomous driving, a simulation of one or more detection devices on a simulated vehicle driving along the given run to obtain simulated sensor data, the simulation including the environment data constructed using the log data;
determining, by the one or more processors, second details regarding detection of objects using the simulated sensor data;
extracting, by the one or more processors, one or more metrics from the first details and the second details; and
evaluating, by the one or more processors, the simulation based on the one or more metrics.

2. The method of claim 1, further comprising selecting, by the one or more processors, the given run based on the log data.

3. The method of claim 2, wherein the selecting of the given run is further based on a type of object appear along a run in the log data.

4. The method of claim 1, further comprising constructing, by the one or more processors, the environment data using the log data.

5. The method of claim 4, wherein the constructing of the environment data includes representing objects in an area encompassing the given run in a scaled mesh.

6. The method of claim 1, wherein the determining of the first details includes determining a relationship between the logged sensor data and objects represented in the environment data.

7. The method of claim 1, wherein the running of the simulation includes retracing rays transmitted from the one or more detection devices and recomputing intensities of the rays off points in the constructed environment data.

8. The method of claim 1, wherein the running of the simulation includes modeling the one or more detection devices based on configuration characteristics or operational settings of a perception system of the given vehicle.

9. The method of claim 1, wherein the determining of the second details includes determining a relationship between the simulated sensor data and objects represented in the environment data.

10. The method of claim 1, wherein the extracting of the one or more metrics includes:
a first metric related to a precision of detected object types;
a second metric related to an amount of recall of an object type; and
a third metric related to an average detection time.

11. A non-transitory, tangible computer-readable medium on which computer-readable instructions of a program are stored, the instructions, when executed by one or more computing devices, cause the one or more computing devices to perform a method for implementing a simulation for sensor data for an autonomous vehicle, the method comprising:
receiving log data collected for an environment along a given run for a given vehicle;
performing, using a software for autonomous driving, a simulated run of the given run using logged sensor data from the log data and environment data constructed using the log data;
determining first details regarding detection of objects during the given run using logged sensor data;
running, using the software for autonomous driving, a simulation of one or more detection devices on a simulated vehicle driving along the given run to obtain simulated sensor data, the simulation including the environment data constructed using the log data;
determining second details regarding detection of objects using the simulated sensor data;
extracting one or more metrics from the first details and the second details; and
evaluating the simulation based on the one or more metrics.

12. The medium of claim 11, wherein the method further comprises selecting the given run based on the log data.

13. The medium of claim 12, wherein the selecting of the given run is further based on a type of object appear along a run in the log data.

14. The medium of claim 11, wherein the method further comprises constructing the environment data using the log data.

15. The medium of claim 14, wherein the constructing of the environment data includes representing objects in an area encompassing the given run in a scaled mesh.

16. The medium of claim 11, wherein the determining of the first details includes determining a relationship between the logged sensor data and objects represented in the environment data.

17. The medium of claim 11, wherein the running of the simulation includes retracing rays transmitted from the one or more detection devices and recomputing intensities of the rays off points in the constructed environment data.

18. The medium of claim 11, wherein the running of the simulation includes modeling the one or more detection devices based on configuration characteristics or operational settings of a perception system of the given vehicle.

19. The medium of claim 11, wherein the determining of the second details includes determining a relationship between the simulated sensor data and objects represented in the environment data.

20. The medium of claim 11, wherein the extracting of the one or more metrics includes:
a first metric related to a precision of detected object types;
a second metric related to an amount of recall of an object type; and
a third metric related to an average detection time.
